(19) United States
(12) Patent Application Publication
(10) Pub. No.: US 2020/0041758 A1
(43) Pub. Date: Feb. 6, 2020

(54) THERMOELECTRICALLY CONTROLLED OPTICAL MIRROR MOUNT

(71) Applicant: BAE SYSTEMS INFORMATION AND ELECTRONIC SYSTEMS INTEGRATION INC., Nashua, NH (US)

(72) Inventor: Erik J. Spahr, Hollis, NH (US)

(21) Appl. No.: 16/053,397

(22) Filed: Aug. 2, 2018

(51) Int. Cl. G02B 7/18; H01L 35/30

(52) U.S. Cl. CPC G02B 7/1815; H01L 35/30

(57) ABSTRACT

An optical assembly is part of an optical system such as a laser communication system on a moveable platform that operates in a range of temperature extremes. The optical assembly has a mount with a plurality of supports that couple an optical mirror to a frame or chassis of the optical system. The supports may be selectively heated or cooled in accordance with their respective coefficients of thermal expansion to reduce, minimize, or eliminate angular drift of the mounted optic or mount. The supports expand or contract to correct for misalignments of the beam reflection angle to improve the accuracy and efficiency of the optical system without significantly increasing size, weight, and power of the optical system.

### BACKGROUND

### Technical Field

The present disclosure relates generally to optical devices. More particularly, the present disclosure relates to an optical assembly that is able to steer a beam to correct for misalignments. Specifically, the optical assembly takes advantage of known coefficients of thermal expansion for a given material forming a base, mount, or support for an optical mirror.

### Background Information

Optical devices, particularly optical devices used in military or industrial laser systems, are normally mounted on moving platforms, regardless of whether the platform is manned or unmanned, such as land vehicles and aerial vehicles. The optical devices require high precision to direct a beam of light to a desired location. However, the precision of an optical device may be reduced when the platform is moved through a range of temperature extremes. For example, a helicopter carrying a laser communication system may be grounded in the desert (i.e., a very hot temperature) and then the helicopter may take off and elevate to a high elevation that exposes the helicopter to much cooler temperatures relative to the desert ground.

Angular drift reduces the precision of the components of an optical device. Angular drift occurs when a mirror or mirror mount in an optical system has a coefficient of thermal expansion (CTE) mismatch between the surrounding chassis or frame to which it is mounted. A CTE mismatch causes the mirror to tilt when one material expands or contracts at a rate different from that of the other material. The resulting forces cause a tilt or shift in the mirror or the mount which results in a misalignment, which can be detrimental to the purpose of the optical device. For example, a misalignment in the optical mirror may preclude a laser communication system from transmitting its information across a laser beam to an intended recipient.

### SUMMARY

Accordingly, issues continue to exist relating to angular drift for optical devices or optical assemblies that are required to operate over a range of temperature extremes. The present disclosure addresses these and other issues by providing an optical assembly, which may be used in a larger laser system or other optical system, that includes supports or mounts for an optical mirror with known coefficient of thermal expansions (CTE) to effectively reduce the mismatch between the mirror and the chassis or frame of the optical assembly and correct for minor misalignments in the system. One possible manner to assist in transferring heat between portions of the optical assembly uses a thermoelectric module, such as a thermoelectric cooler (TEC).

In accordance with one aspect, an embodiment of the present disclosure may provide an optical assembly comprising: an optical mirror adapted to receive and reflect a beam of electromagnetic radiation; a first support coupled to the optical mirror having a first CTE; a second support coupled to the optical mirror having a second CTE; a first tilt axis of the optical mirror; a temperature operating range, wherein the optical mirror tilts about the first tilt axis as the first support and the second support expand and contract in response to the first CTE and the second CTE, respectively, as temperatures of the first support and the second support vary within the temperature operating range. This exemplary embodiment or another exemplary embodiment may further provide a variable optical beam deflection angle; a first temperature within the temperature operating range; a different second temperature within the temperature operating range; wherein the mirror tilts about the first tilts axis to vary the variable optical beam deflection angle as the temperature changes from the first temperature to the second temperature. This exemplary embodiment or another exemplary embodiment may further provide a generally linear relationship of the variable optical beam deflection angle versus the temperature difference between the first temperature and the second temperature. This exemplary embodiment or another exemplary embodiment may further provide wherein a greater temperature difference between the first temperature and the second temperature results in a greater optical beam deflection angle than a lesser temperature difference between the first temperature and the second temperature. This exemplary embodiment or another exemplary embodiment may further provide a range of the variable optical beam deflection angle from about 1 microradian (urad) to about 1 milliradian (mrad); and a range of the temperature difference between the first temperature and the second temperature in a range from about 1° C. to about 125° C. This exemplary embodiment or another exemplary embodiment may further provide wherein the first CTE is different than the second CTE. This exemplary embodiment or another exemplary embodiment may further provide a first surface and an opposing second surface of the optical mirror; an insulator coupled to the second surface of the optical mirror; a portion of the first support connected to the insulator; a portion of the second support connected to the insulator; wherein the insulator is positioned between the optical mirror and the first and second supports. This exemplary embodiment or another exemplary embodiment may further provide a first surface and an opposing second surface of the optical mirror; wherein the first support and second support are offset from the second surface of the optical mirror; a thermoelectric module coupled to the first support and the second support to exchange heat between the first support and the second support; wherein the first and second supports expand or contract in response to the heat exchanged between the first support and the second support. This exemplary embodiment or another exemplary embodiment may further provide a spacing distance defined between the first support and the second support; a first end of the thermoelectric module coupled to the first support; a second end of the thermoelectric module coupled to the second support; wherein the thermoelectric module occupies the spacing distance between the first and second supports offset from the second surface of the optical mirror. This exemplary embodiment or another exemplary embodiment may further provide a first temperature sensor associated with the first support; a second temperature sensor associated with the second support; a computer having a processor and a non-transitory computer readable storage medium; a first electrical connection between the thermoelectric module and the computer, wherein the storage medium has instructions encoded thereon that, when executed by the processor, implement operations to exchange heat between the first support and the second support; a second electrical connection between the first temperature sensor and the computer; and a third electrical connection between the second temperature sensor and the computer. This exemplary embodiment or another exemplary embodiment may further provide a simultaneously execution of signals transmitted along the second and third electrical connections by the processor; a command transmitted along the first electrical connection to the thermoelectric modules to selectively change the temperature of the first support relative to the second support to tilt the mirror about the first tilt axis as the first support expands or contracts relative to the second support. This exemplary embodiment or another exemplary embodiment may further provide a direct conduction of heat between the thermoelectric module and the first support; a direction conduction of heat between the thermoelectric module and the second support. This exemplary embodiment or another exemplary embodiment may further provide a thermoelectric module coupled to the first support configured to selectively (i) heat the first support to expand the first support, and (ii) cool the first support to contract the first support; wherein the second CTE approximates zero such that the second support is substantially invariable over the temperature operating range; a variable optical beam deflection angle; wherein the mirror tilts about the first tilts axis to vary the variable optical beam deflection angle as the thermoelectric module changes the temperature of the first support to expand or contract.

In another aspect, an exemplary embodiment of the present disclosure may provide a method for an optical assembly comprising: sensing a first temperature of a first support having a first CTE coupled to an optical mirror tiltable about a first tilt axis; sensing a second temperature of a second support having a second CTE coupled to the optical mirror; determining whether the optical mirror needs to be tilted about the first tilt axis based, at least in part, on the first temperature, the first CTE, the second temperature, and the second CTE; tilting the optical mirror; and minimizing angular drift of the optical mirror by reducing an alignment mismatch between the optical mirror and a frame of the optical assembly. This exemplary embodiment or another exemplary embodiment may further provide transferring heat to or from the first support in response to sensing the first temperature. This exemplary embodiment or another exemplary embodiment may further provide transferring heat to or from the second support in response to sensing the second temperature. This exemplary embodiment or another exemplary embodiment may further provide correcting a beam reflection angle from the optical mirror in response to the transferring heat to or from the first support. This exemplary embodiment or another exemplary embodiment may further provide correcting the beam reflection angle within an angular range from about 1 urad to about 1 mrad, wherein the angular range is less than correction capabilities effectuated by mechanical devices. This exemplary embodiment or another exemplary embodiment may further provide expanding the first support linearly along a support axis that is orthogonal to the first tilt axis; and contracting the first support linearly along the support axis. This exemplary embodiment or another exemplary embodiment may further provide moving the optical assembly through an environment that varies in temperature ranging from about −54° C. to about 71° C., wherein temperature variations cause angular drift of the mirror thereby reducing efficiency of the optical assembly; and eliminating angular drift by removing the alignment mismatch between the optical mirror and the frame of the optical assembly.

In yet another aspect, an exemplary embodiment of the present disclosure may provide an optical assembly is part of an optical system such as a laser communication system on a moveable platform that operates in a range of temperature extremes. The optical assembly has a mount with a plurality of supports that couple an optical mirror to a frame or chassis of the optical system. The supports may be selectively heated or cooled in accordance with their respective coefficients of thermal expansion to reduce, minimize, or eliminate angular drift. The supports expand or contract to correct for misalignments of the beam reflection angle to improve the accuracy and efficiency of the optical system without significantly increasing size, weight, and power of the optical system.

### BRIEF DESCRIPTION OF THE SEVERAL VIEWS OF THE DRAWINGS

Sample embodiments of the present disclosure are set forth in the following description, is shown in the drawings and is particularly and distinctly pointed out and set forth in the appended claims.

FIG. 1 (FIG. 1) is a diagrammatic first side elevation view of an optical assembly in accordance with the present disclosure.

FIG. 2 (FIG. 2) is a diagrammatic side elevation view of the optical assembly having a thermoelectric module.

FIG. 3 (FIG. 3) is a diagrammatic side elevation view of an alternative embodiment of an optical assembly in accordance with the present disclosure having a first tilt axis and a second tilt axis.

FIG. 4 (FIG. 4) is a diagrammatic first end elevation view of the alternative embodiment of the optical assembly having two tilt axes.

FIG. 5 (FIG. 5) is an operational diagrammatic view of the optical assembly of FIG. 1.

FIG. 6 (FIG. 6) is a diagrammatic operational side elevation view of the optical assembly of FIG. 2.

FIG. 7 (FIG. 7) is a diagrammatic operational side elevation view of the second embodiment of the optical assembly of FIG. 3.

FIG. 8 (FIG. 8) is a first end view taken along line 8-8 in FIG. 7 depicting the operational view of the alternative embodiment of the optical assembly.

FIG. 9 (FIG. 9) is an exemplary flowchart in accordance with a method of the optical assembly.

Similar numbers refer to similar parts throughout the drawings.

### DETAILED DESCRIPTION

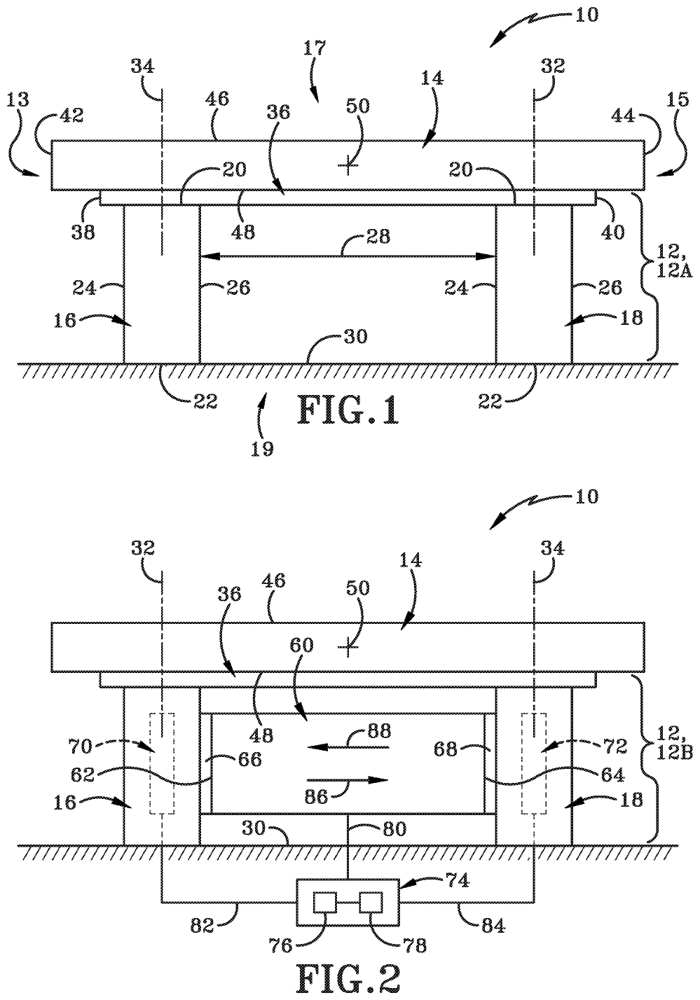

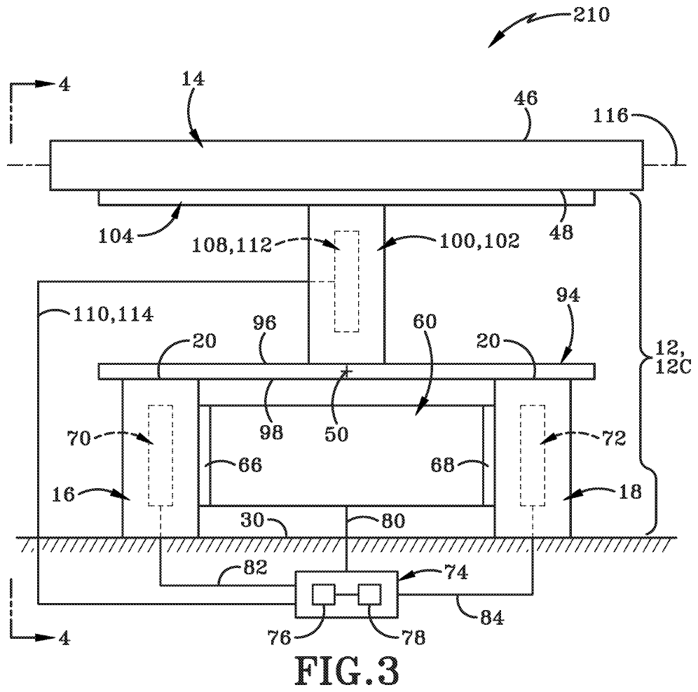

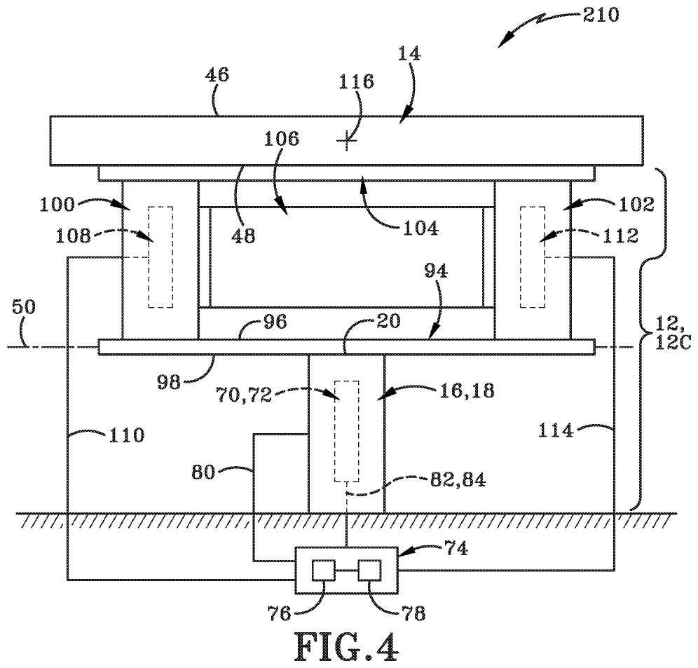

An optical assembly in accordance with the present disclosure is shown generally at 10. Optical assembly 10 includes a mirror mount 12 configured to support a mirror 14. A first embodiment of mount 12 is depicted in FIG. 1 as 12A. A second embodiment of mount 12 is depicted in FIG. 2 as 12B. A third embodiment of mount 12 is depicted in FIG. 3 and FIG. 4 as 12C. The optical assembly having mount 12C is denoted as optical assembly 210. Each embodiment of mount 12 utilizes principles pertaining to coefficients of thermal expansion to move or tilt mirror 14 to compensate for alignment drift of mirror 14 in the optical assembly 10. Thus, optical assembly 10 (or optical assembly 210) assists with alignment correction of mirror 14 by inducing mirror tilt without requiring additional mechanical components or moving parts to point or steer a beam reflecting from the mirror 14.

FIG. 1 depicts mount 12A as including a first support 16 and a second support 18. First support 16 and second support 18 may also be referred to herein as a post, a pedestal, a base, a pillar, or a column.

Optical assembly 10 includes a first end 13 opposite a second end 15 defining a longitudinal direction therebetween. Optical assembly 10 further includes a top 17 opposite a bottom 19 defining a vertical direction therebetween. Optical assembly 10 further includes a first side opposite a second side defining a transverse direction therebetween wherein the transverse direction is orthogonal to the longitudinal direction and the vertical direction.

Each support 16, 18 includes a top end 20 opposite a bottom end 22. Each support 16, 18 further includes a first end 24 and a second end 26. First end 24 of each support 16, 18 is oriented towards the first end 13 of optical assembly 10 and the second end 26 of each support 16, 18 is oriented towards the second end 15 of optical assembly 10. First and second ends, 24, 26 of each support 16, 18 extend generally spaced apart and parallel from each other between top end 20 and bottom end 22. Each support post 16, 18 is spaced apart by a distance 28 such that the surface area defined by the second end 26 on the first support 16 faces the surface area defined by the first end 24 of the second support 18. The spacing distance 28 between the first support 16 and the second support 18 may be suitably configured to provide adequate support to mirror 14.

The bottom end 22 of each support 16, 18 is connected to a chassis or frame 30 of optical assembly 10. In one particular embodiment, the first support 16 and the second support 18 are orthogonally connected such that a major vertical axis associated with each respective support 16, 18 orthogonally intersects frame 30. Particularly, a first vertical axis 32 is associated with a first support 16 and second vertical axis 34 is associated with the second support 18. Each axis 32, 34 may extend centrally through the first and second supports 16, 18, respectively. The first vertical axis 32 is parallel and spaced apart from the second vertical axis 34. A width of the first support 16 is aligned with the longitudinal direction of the optical assembly 10 and defined between first end 24 and second end 26 of the first support 16. A width associated with the second support 18 is aligned in a longitudinal direction of the optical assembly 10 between the first end 24 and the second end 26 of the second support 18. In one particular embodiment, the respective widths of the first and second support 16, 18 are similar. However, it is entirely possible to have the width from one of the supports, either 16 or 18, to be greater than or less than the width of the other support. In one particular embodiment, the dimensions of the first support 16 and the second support 18 are identical under standard conditions for temperature and pressure (STP), which is a temperature of zero degrees Celsius and a pressure of one Atmosphere (ATM). In another embodiment, the dimensions of the first support 16 and the second support 18 may be identical at normal temperature and pressure (NTP) which is a temperature of 20 degrees Celsius and an absolute pressure of one ATM. In other embodiments, the dimensions of the first support 16 and the second support 18 may be identical at least one temperature.

The top end 20 of each support 16, 18 is connected to an insulating layer 36 that is longitudinally oriented and extends above the first support 16 and the second support 18 between the supports 16, 18 and the mirror 14. In one particular embodiment, the length of the insulator 36 between its first end 38 and its second end 30 is longer than the distance in the longitudinal direction between the first end 24 of the first support 16 to the second end 26 of the second support 18. In another particular embodiment, the length of the insulator 36 is significantly greater than its vertical height. Furthermore, a plurality of insulators could be used wherein the number of insulators corresponds to the number of supports such that one insulator insulates one support. Insulator 36 is a thermal insulator that prevents heat from transferring between either the support 16 or the support 18 into the mirror 14. Particularly, insulator 36 is configured to reduce, as much as possible, the amount of heat incidentally conducted to the mirror 14 inasmuch as heat driven into the mirror 14 would result in curvature of the same. In one particular embodiment, insulator 36 may be fabricated from a ceramic material with a high insulation value.

Mirror 14 includes a first end 42 opposite a second end 44 aligned in the longitudinal direction. Mirror 14 further includes top end 46 opposite a bottom end 48. The top end 46 of mirror 14 defines a major surface area as configured to reflect incoming light as will be described in greater detail below. The top end 46 and the bounded and defined major surface area is larger than the minor surface area defined by the thickness of the mirror 14 between the first end 46 and the second end 48. The bottom end 48 of mirror 14 is coupled with the insulator 36 to position the insulator 36 between the mirror 14 and the supports 16, 18. A tilt axis 50 is adjacent the longitudinal center of mirror 14 which extends in the transverse direction (into and out of the page). Tilt axis 50, aligned in the transverse direction, is a single axis about which the mirror 14 is configured to rotate or pivot or tilt. Thus, optical assembly 10, having mount 12A as substantially described and depicted in FIG. 1, is considered a single axis optical assembly 10. Alternatively, optical assembly 10 may be referred to as a single axis adjustment for optical assembly 10.

Mirror 14 is an optical device which can reflect light. Usually the term “mirror” refers to devices where the angle of reflection equals the angle of incidence. This means that diffraction gratings, for example, are not usually considered mirrors, although they can also reflect light. However, for the purpose of this disclosure, the term mirror refers to any optical device that reflects light or electromagnetic radiation, regardless of the angle of reflection. The mirror surfaces does not need to be flat; there are mirrors with a curved reflecting surface. In one particular embodiment, mirror 14 and optical assembly 10 relates to laser technology and general optics, thus mirror 14 may be a dielectric mirror that includes multiple thin dielectric layers (not shown). Dielectric mirror 14 uses the combined effect of reflections at the interfaces between the different layers. A frequently used design is that of a Bragg mirror (quarter-wave mirror), which is a simple design and provides high reflectivity at a particular wavelength (the Bragg wavelength). In contrast to some metal-coated mirrors, dielectric mirrors are usually made as front surface mirrors, which means that the reflecting surface is at the front surface, so that the light does not propagate through some transparent substrate before being reflected. That way, not only possible propagation losses in the transparent medium are avoided, but most importantly additional reflections at the front surface, which could be particularly relevant for non-normal incidence. However, it is to be entirely understood that mirror 14 may be an advanced type of metal-coated mirror. A metal coated mirror may have additional thin film layers on top of the metallic coating in order to improve the reflectivity and/or to protect the metallic coating against oxidation. Different metals can be used, e.g. gold, silver, copper and nickel/chrome alloys.

Mirror 14 may be curved having a spherical surface, characterized by some radius of curvature R. A mirror with a concave (inwards-curved) surface acts a focusing mirror, while a convex surface leads to defocusing behavior. Apart from the change of beam direction, such a mirror acts like a lens. For normal incidence, the focal length (disregarding its sign) is simply R/2, i.e., half the curvature radius. For non-normal incidence with an angle θ against the normal direction, the focal length is (R/2)·cos θ in the tangential plane and (R/2)/cos θ in the sagittal plane. There are also parabolic mirrors, having a surface with a parabolic shape. For tight focusing, one exemplary system may use off-axis parabolic mirrors, which allow one to have the focus well outside the incoming beam. Additionally, systems may use a spherical mirror to effectuate the focus of the incoming beam.

Mirror 14 may be either circular, square or another shape when viewed from above. However, in each case, mirror 14 has a defined tilt axis, such as transverse first tilt axis 50, that enables the mirror 14 to tilt or pivot thereabout. Thus, regardless of the configuration of the mirror 14, the angle 54 is created about only a single axis. This may be effectuated by the supports 16, 18 regardless of their position and connection with the mirror 14. As discussed above, supports 16, 18 may be closely adjacent each other or spaced apart via a spacing distance 28. Alternatively, support 16, 18 may be located adjacent the perimeter of mirror 14 or alternatively, it could be located near the central vertical axis.

Optical assembly 10, having mount 12A, is considered to be a passive adjustment because it does not utilize thermoelectric or other electrical components to rotate, pivot, or tilt the mirror 14 about the tilt axis 50. Movement of mirror 14 is effectuated by fabricating the first support 16 and the second support 18 from materials that have different coefficients of thermal expansion. Stated otherwise, the first support 16 has a first coefficient of thermal expansion (CTE) and the second support 18 has a second CTE that is different from the first CTE. In one particular embodiment, the first and second supports 16, 18 are both fabricated from metals or other sufficiently rigid materials that have different CTEs. Further, in one particular example, one of the supports, such as first support 16, may be fabricated from aluminum alloy or another material and the other support, such as second support 18, may be fabricated from Invar or another alloy with a substantially different coefficient expansion. Invar is also generically known as 64 FeNi and is a nickel-iron alloy notable for its uniquely low CTE, such that it is substantially negligible. Other suitable materials include, but are not limited to, sitall and zerodur.

FIG. 2 depicts optical assembly 10, as a single axis optical assembly, utilizing a second embodiment mount 12B. It should be noted that similar reference numerals/elements utilized throughout the specification refer to similar parts and portions of optical assembly 10, and thus similar reference numerals/elements are not repeated for brevity. Mount 12B includes first support 16 and second support 18 positioned below the insulator 36 and connected thereto to support mirror 14 so that it may tilted about the tilt axis 50. Mount 12B further includes a thermoelectric module 60. Thermoelectric module 60 may be connected to the first support 16 and the second support 18. In one particular embodiment, the thermoelectric module 60 may be connected to the first support 16 and the second support 18 and occupy the spacing distance 28 between the second surface 26 of the first support and the first end 24 of the second support 18. However, it is to be entirely understood that in other particular embodiments, the thermoelectric module may be in operative communication with the respective support 16, 18 and may be located at locations other than the space between the supports. For example, it is entirely possible for the thermoelectric module to be positioned below the bottom ends 22 of the respective first and second supports 16, 18. Alternatively, it may be possible to position the thermoelectric module adjacent the top end 20 of each support 16, 18. Furthermore, it may be possible to position the thermoelectric module along the outer surfaces of the support 16, 18 such that the thermoelectric module surrounds the supports 16, 18. Even further, there may be a plurality of thermoelectric modules that are individually coupled to a single support.

The thermoelectric module 60 may include a first end 62 and a second end 64. The first end 62 of thermoelectric module 60 may be coupled with the first support 16. In one particular embodiment, a thermal conductive layer 66 is positioned between the first end 62 and the second end 26 of the first support 16. The thermal conductive layer 66 may be a layer of foil to effectuate the transfer of heat between the thermoelectric module 60 and the first support 16. In one particular embodiment, the layer 66 may be formed from a tin-based foil or an indium-based foil. Alternatively, the layer 66 need not be a foil and may be fabricated from other thermal compounds, such as thermal adhesive, that are used to join the first end 62 of thermoelectric module 60 to the second end 26 of the first support 16. A second thermal layer 68 is used to attach the second end 64 of the thermoelectric module 60 to the first end 24 of the second support 18. Similar to the first thermal layer 66, the second thermal layer 68 may be formed from a layer of foil or another thermal conductive compound. For ease of manufacturing, the first thermal layer 66 and the second thermal layer 68 are typically the same material. However, it is entirely possible that different thermal layers may be utilized to couple the respective ends of the thermoelectric module 60 to the supports 16, 18. The interface between the first thermal layer 66 and the first end 62 of the thermoelectric module 60 may entirely occupy the vertical length of the first end 62 of the thermoelectric module 60. In another particular embodiment, the thermal layer 66 may occupy only a portion of the first end 62 of the thermoelectric module 60 such that the interface between the thermal layer 66 and the first end 62 is less than the entire vertical length of the first end 62. Similarly, the interface of the thermal layer 68 with the second end 64 of the thermoelectric module 60 may occupy the entire vertical length of the second end 64. Layer 66 and layer 68 assist in the connection of the ends of the thermoelectric module 60 to the respective supports 16, 18. The layers 66, 68 effectuate good contact and good heat transfer fabricated from tin or indium that fills in voids to insure good contact between the module 60 and the supports 16, 18. Alternatively, layer 66, 68 could be fabricated from a chemical adhesive that is thermally conductive, such as a thermally conductive adhesive.

In one particular embodiment, thermoelectric module 60 may be a thermoelectric cooler (TEC) that uses the Peltier effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current. Thermoelectric module 60 may also be referred to as a Peltier device, Peltier heat pump, or a solid state refrigerator. It can be used either for heating or for cooling. It can also be used as a temperature controller that either heats or cools.

With continued reference to FIG. 2, mount 12B may further include a first sensor 70 to sense the temperature of support 16. In one embodiment, sensor 70 may be embedded in the first support 16. The first sensor 70 may be centered along the vertical axis 32 and be positioned approximately halfway between the top end 20 and the bottom end 22 of the first support 16 such that the first sensor 70 can be substantially vertically centered. However, it is entirely possible for the first sensor 70 to be located at alternative positions within the first support 16. For example, the first sensor 70 may be biased and offset towards the bottom end 22 or alternatively, it could be biased and offset towards the top end 20. In one particular embodiment, sensor 70 is a thermistor. In other embodiments, the first sensor 70 may be a resistance-temperature detector thermocouple or a negative temperature coefficient thermistor or a semiconductor-based sensor, or the like. Alternatively, sensor 70 may be remote from the first support 16 and be configured to take the temperature thereof through the use of external measuring means, such as an infrared sensor, that effectuates temperature determination through a non-contact relationship. Stated generally, the first sensor 70 is associated with the first support 16 and senses the temperature thereof.

A second sensor 72 may be embedded in the second support 18. Second sensor 72 may be identical to the first sensor 70; however, it need not be. For example, while the first sensor 70 may be a thermistor, the second sensor 72 may be a resistance-temperature detector thermocouple. However, for ease of manufacturing, it is likely that the sensors 70, 72 are similar in make and manufacture. Similar to the first sensor 70, the second sensor 72 may be vertically centered within the second support 18 and longitudinally aligned along the vertical axis 34 of the second support 18. Stated generally, the second sensor 72 is associated with second support 18 and senses the temperature thereof.

With continued reference to FIG. 2, optical assembly 10 having mount 12B may further include a computer 74 having a processor 76 coupled with a memory or at least one non-transitory computer readable storage medium 78. The thermoelectric module 60 is coupled with the computer 74 via connection 80. The first sensor 70 is coupled with the computer 74 via connection 82. The second sensor 72 is connected with the computer 74 via connection 84. The connections 80, 82, and 84 may be wired or wireless connections. The connections effectuate the transmission of data and data signals between the respective elements of optical assembly 10. For example, data signals from first sensor 70 may be transmitted along connection 82 to computer 74 that may be received in the processor 76 and execute instructions recorded on the memory 78 in response to the received data from first sensor 70. Processor 76 may send instructions along connection 80 to the thermoelectric module 60 to initiate a transfer of heat in response to the temperature sensed by the first sensor 70. Similarly, the computer 74 receives the temperature sent by second sensor 72 along connection 84. The processor 76 may simultaneously process the signals relating to temperature of the second sensor 72 and direct signals along connection 80 to thermoelectric modules 60 to effectuate the transfer of heat between the first support 16 and the second support 18. Similar to the first embodiment, the mount 12B has first support 16 and second support 18 which may be fabricated from different materials having different CTE values. Thus, the transfer of heat effectuated by the thermoelectric module 60 may effectuate the tilting movement of the mirror 14 about tilt axis 50. Furthermore, since mount 12B is considered an active system that transfers heat through the thermoelectric module 60, it is possible that the CTE value of the first support 16 and the second support 18 could be identical. It is possible to have a thermoelectric module 60 between two identical supports 16, 18 that expand and contract in response to the transfer of heat reflected by the thermoelectric module 60. The thermoelectric module 60 may direct heat towards the second support 18 (thereby cooling the first support 16) as indicated by arrow 86. Alternatively, the thermoelectric module 60 may direct heat towards the first support 16 (thereby cooling second support 18) as indicated by arrow 88.

In one particular embodiment, the first CTE of the first support 16 and the second CTE of the second support 18 are each uniform across the entire vertical length of each respective support 16, 18. However, it is possible for the temperature profile to be non-uniform across the vertically aligned length of each support 16, 18. In this instance, at the interface between the thermoelectric module 60 and the first support 16, when heat is being pumped into the first support 16 as indicated by arrow 88, the interface would be warmer or hotter than the opposite side of the support 16. Thus, there would be slightly more expansion at the interface than there would be at the other side of the support 16. Thus, there may be some non-uniformity in the temperature profile and the expansion rate even though the CTE is uniform across the entire length of the support 16. The gradient can be reduced by reducing the size of the support, either 16 or 18, such that the support may heat up or cool at a faster rate so that the entire temperature of the respective support 16, 18 can approach an equilibrium such that there is a uniform expansion across the base.

In accordance with an aspect of the present disclosure, an optical system implementing assembly 10 with mount 12B accomplishes its mirror tilting by heating one support 16, and possibly while simultaneously cooling the other support 18. The manner in which the heating and cooling is effectuated between the supports 16, 18 may be accomplished in another alternative way other than those which have been described above. For example, a TEC 60 could be located below the supports 16, 18 such that it is not located in a spaced distance 28 between the same. Alternatively, there may be two TECs 60 where each respective TEC 60 is coupled to one support, either 16 or 18, and each respective TEC 60 is connected to its own separate heat sink (not shown). Alternatively, a resistive heater may be utilized to heat one of the supports 16, 18 while another support 16, 18 is maintained at a standard temperature in a conventionally known manner.

FIG. 3 and FIG. 4 depict an optical assembly 210 in accordance with another aspect of the present disclosure having a two-axis adjustment. The mount 12C that effectuates the two-axis adjustment includes at least four supports. The first support 16 and the second support 18 are coupled and supported by the chassis in a manner similar to the other mounts 12A, 12B. The top ends 20 of the first support 16 and the second support 18 are coupled with a rigid insulative plate 94 that defines the tilt axis therethrough. Tilt axis 50 is a transverse axis and may be considered a first tilt axis when using mount 12C. The insulative rigid plate 94 is longitudinally aligned and extends above the top end 20 of each support 16, 18. Support 94 includes a upwardly facing first surface 96 and a downwardly facing bottom surface 98. Downwardly facing bottom surface 98 is engaged with a top end 20 of first support 16 and second support 18. The upwardly facing top surface 96 of support 94 supports two more pedestals or posts or additional supports thereabove that are oriented 90 degrees or orthogonal relative to the first and second supports 16, 18. Particularly, as depicted in FIG. 4, a third support 100 and a fourth support 102 are positioned above the longitudinal support 94 and support an optical mirror 14 thereabove that is insulated by an insulating layer 104. A second thermoelectric module 106 is positioned between the third support 100 and the fourth support 102. A third sensor 108 may be embedded in the third support 100 and is connected with computer 74 via connection 110. A fourth sensor 112 may be embedded in the fourth support 102 and is connected with computer 74 via connection 114.

The alignment of the third support 100 and the fourth support 102 should be orthogonal to the first and second support 16, 18 to thereby establish a second tilt axis 116 that is orthogonal to the first tilt axis 50. Similar to the first and second supports 16, 18, the third and fourth supports 100, 102 are able to be controlled via the computer 74 to effectuate a tilt of the mirror 14 about the second tilt axis 116 that is orthogonal to the first tilt axis 50 in response to the sensed temperatures of the third and fourth supports 100, 102. Thus, the optical assembly 210 utilizing mount 12C is a two-axis adjustment system that is configured to provide alignment drift correction logic implemented via the processor 76 that can tilt the mirror 14 in any direction along a two-dimensional plane.

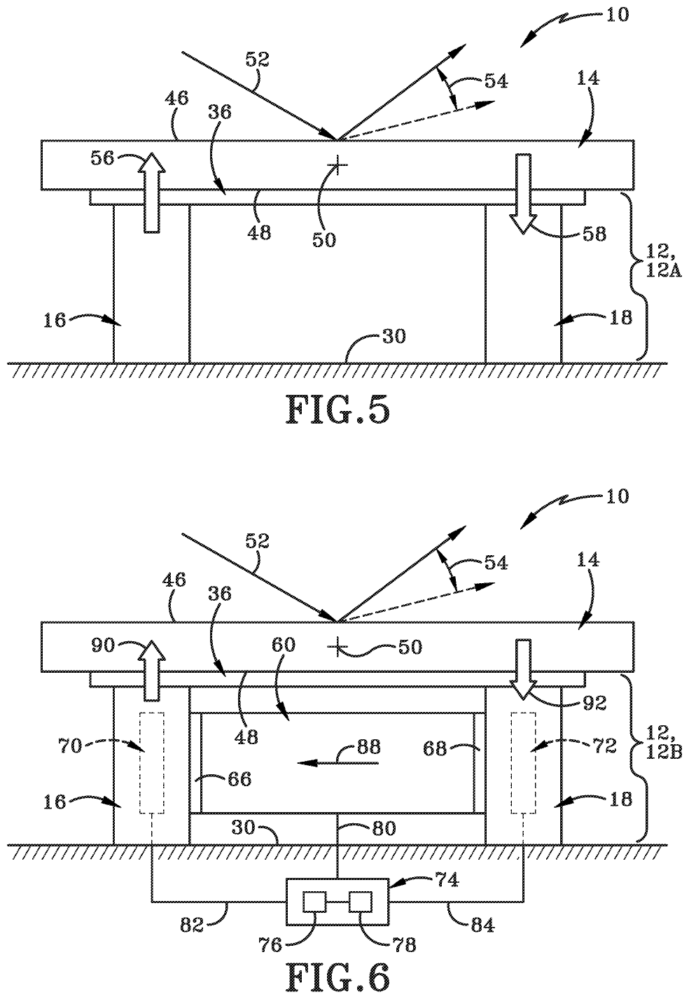

In accordance with some exemplary aspects of the present disclosure, the optical assembly 10 having mount 12A or 12B, or optical assembly 210 having mount 12C minimizes angular drift of the optical mirror by reducing an alignment mismatch between the optical mirror and a frame of the optical assembly. Having thus described the structure of the optical assembly 10, 210, the operation thereof is discussed with reference to FIGS. 5-8.

In operation and with reference to FIG. 5, mirror 14 is configured to tilt about tilt axis 50 in response to expansion and/or contraction of the first support 16 and/or the second support 18. The movement or tilting of mirror 14 about tilt axis 50 is configured to steer or direct a beam 52 by changing the deflection angle between a variety of deflection vectors. As mentioned above, optical assembly 10 having mount 12A is configured to be installed as part of an optical system on a platform as configured to be exposed to very rugged terrain and harsh environments. Typically, operating parameters for the optical system in which optical assembly 10 is mounted may be in a range from about −54 degrees Celsius to about 71 degrees Celsius. Thus, the temperature range difference may be in a range from about one degree Celsius to about 125 degrees Celsius (71° C.−(−54° C.)=125° C.).

When other components of the optical system experience alignment drift due to temperature changes, it is necessary for the optical assembly 10 to compensate for the alignment drift due to temperature differences by effectuating the expansion or contraction of the supports 16, 18 through the use of their known CTEs. For example, if the first support 16 has a different CTE than the second support 18, then the temperature associated and experienced by the optical assembly 10 may cause the first support 16 to expand as indicated by arrow 56. The same temperature may cause the second support 18 to contract as indicated by arrow 58. In scenarios where one of the supports, either 16 or 18, is fabricated from Invar or another material having a very low CTE, there may be very little to no expansion or contraction. Thus, only the other of the supports, 16 or 18, would expand or contract to effectuate tilt of the mirror 14 about the tilt axis 50 to change the optical reflection or deflection angle as indicated at 54. In one particular embodiment, the expansion and contraction of the first support 16 and the second support 18 occurs linearly along the respective vertical axes. Stated otherwise, the first support 16 is configured to linearly expand along its vertical axis 32 and linearly contract along its vertical axis 32. Second support 18 is configured to linearly expand along its vertical axis 34 and linearly contract along its vertical axis 34 depending upon the temperatures subjected to the optical assembly 10. Furthermore, it is not necessary that one of the supports expand while the other contracts. For example, it is entirely possible that both expand simultaneously or both contract simultaneously but at different rates. Thus, the change in the optical deflection angle 54 can be accomplished by a first support 16 that expands in the direction as indicated by arrow 56 along its vertical axis 32 at a rate faster than the expansion of the second support 18. Alternatively, the second support 18 could expand faster than the expansion rate of the first support 16 to accomplish the change in the optical deflection angle 54 of the beam 52. Similarly, the first support 16 could contract at a faster rate than the second support 18. Since the CTEs of the materials are known that are used to fabricate the first support 16 and the second support 18, the expansion rates associated with the supports for a given temperature can be optimized and engineered to account for and compensate for the alignment drift due to temperature changes of other parts of the optical system within which the optical assembly 10 is provided. In one example, the rate of expansion is a linear function of temperature change versus the resultant deflection.

In operation and with reference to FIG. 6, the optical assembly 10 having mount 12B is shown in operation where the first support 16 is expanded as indicated by arrow 90 and the second support 18 is contracted as indicated by arrow 92. In this instance, heat would be directed in the direction of arrow 88 towards the first support 16 thereby cooling the second support 18 via thermoelectric module 60. The resultant change in the beam angle 54 is able to accomplish and compensate for alignment drift of other portions of the optical system by tilting the mirror 14 about the tilt axis 50. As the temperature in the optical system continues to change, the first sensor 70 and the second sensor 72 continue to sense and send signals to the computer 74 that are processed by the processor 76. The processor 76 utilizes instructions and data base tables stored in the memory 78 to determine when the thermoelectric module 60 needs to be adjusted to compensate and correct for temperature differences that will result in varying expansions and contractions in the supports 16, 18 to change the beam angle 54 in accordance with the desired pointing of the beam 52.

First sensor 70 observes the temperature of the first support 16 at a first time. Simultaneously, or at least near in time, the second sensor 72 observes and senses the temperature of the second support 18 at, or near, the first time. The computer 74, namely the processor and the associated memory, cooperate to effectuate alignment drift correction logic which determines whether the first support 16 or the second support 18 needs to be adjusted to compensate for the difference of the optical deflection angle 54. If the alignment drift correction logic determines that the optical angle correction 54 is incorrect and thus needs to be corrected, the processor sends signals to the thermoelectric module 60. The signals direct the thermoelectric module 60 to change at least one temperature of either the first support 16 of the second support 18. For example, the thermoelectric module 60 may increase the temperature and thus expand the first support 16 while maintaining the temperature of the second support 18. Alternatively, the thermoelectric module 16 may decrease the temperature of the second support 18, thus contracting in the direction of arrow 92, while maintaining or changing the temperature of the first support 16. Even further, the thermoelectric module 60 may simultaneously increase the temperature in the first support 16, thus expanding the first support 16 in the direction of arrow 90, while decreasing the temperature of the second support 18, thus contracting the second support 18 in the direction of arrow 92. Expansion and contraction of the respective first and second supports 16, 18 and their direct connection with the insulating layer 36 which is directly connected with the second surface 48 of the mirror 14 enables the mirror 14 to tilt about the tilt axis 50.

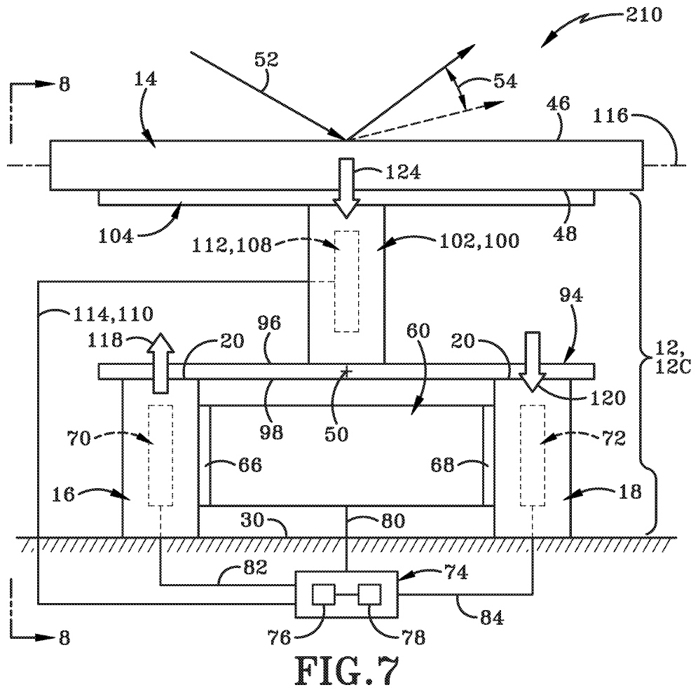

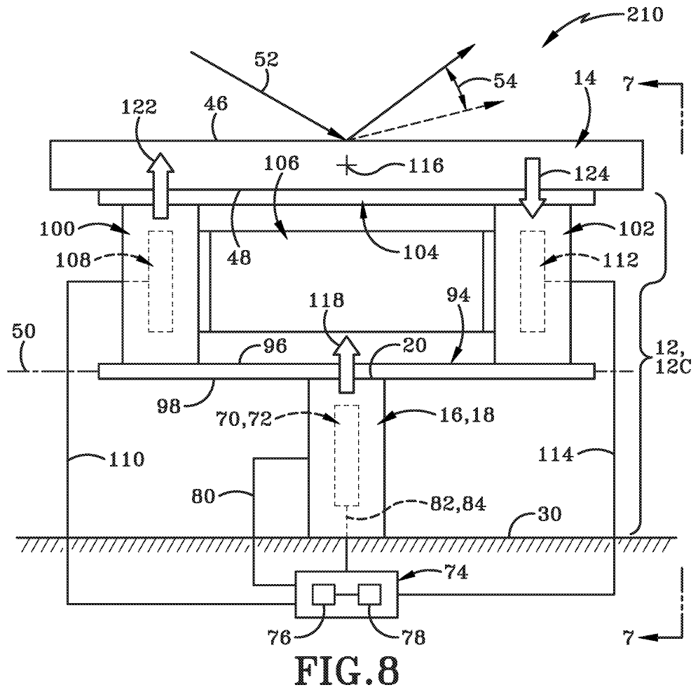

In operation and with reference to FIG. 7 and FIG. 8, the two-axis adjustment mount 12C depicts that the first sensor 70 and the second sensor 72 can cooperate to tilt the support 94 about the first axis 50 as indicated by arrows 118 and 120, respectively. Simultaneous to the tilting of support 94 about tilt axis 50, the second thermoelectric module 106 can direct the heat transfer between the third support 100 and the fourth support 102. FIG. 8 depicts that the third support 100 is expanding indicated by arrow 122 and the fourth support 102 is contracting as indicated by arrow 124. This enables the mirror 14 to tilt about the second tilt axis 116. The connection of the components of mount 12C together establishes that the mirror 14 tilts about the two axes 50, 116 to correct the incoming beam 52 to provide an optical reflection angle change 54 as desired by the system to meet the overall system objectives.

Rugged and challenging environments often pose difficult tasks to construct and implement hardware and software that can successfully operate in the environment. For example, in military specifications that have challenging temperature profiles, systems are sensitive to any small drift in the mechanics of the system, such as mounts or mirrors in optical systems. In accordance with one aspect of the present disclosure, optical assembly 10, 210 is mounted on and carried by a moveable platform, regardless of whether it is manned or unmanned, such as a helicopter or a drone. The aerial platform can often travel between great altitudes and thus it is subjected to a variety of temperatures. For example, in a grounded desert environment, the aerial platform may be subjected to temperatures greater than 40 degrees Celsius (° C.) and when flying at a significantly high altitude, the platform may experience temperatures less than about −20° C. Thus the components of the optical assembly 10 or 210 need to account for the temperature operating range of the optical assembly 10 or 210.

In accordance with another aspect of the present disclosure, optical assembly 10 or 210 is used in conjunction with a laser or laser source. In one particular embodiment, the optical assembly 10 or 210 may be positioned closely adjacent the optical mirrors 14 that generate the laser beam 52 in order to guide, point, and steer the laser beam 52 outwardly from the laser assembly or the aerial platform (not shown). Alternatively, optical assembly 10 or 210 may be part of the receiving electronics for a laser receiver that is used to point and steer and receive laser beam 52 generated from a source and reflect the same to a receiving module.

In accordance with one aspect, optical assembly 10 or 210 is free from moving parts that effectuate the tilt or steering of beam 52 relative to the tilt of the tilt axis 50. However, it is entirely possible for optical assembly 10 or 210 to utilize a micro electromechanical device (MEMS). Alternatively, the optical assembly 10 or 210 utilizing first and second supports 16, 18 having a first CTE and a second CTE may be used in conjunction with a Gimbal of another type of moving device that effectuates tilt of the mirror 14 about the tilt axis 50. Although mechanical devices could be utilized to further adjust alignment of the mirror 14 about tilt axis 15, it may not be desirable in all applications inasmuch as optical assembly 10 or 210 reduces size, weight, and power of traditional optical devices by eliminating the use of mechanical movement to drive the mirror 14 to tilt about the tilt axis 50. In contradistinction, movement of the mirror 14 about the tilt axis 50 is effectuated through heat transfer and taking advantage of natural CTE properties of the materials utilized to fabricate the first support 16 and second support 18.

Optical assembly 10 or 210 compensates for small misalignments in the optical system. Particularly, the compensation for the small misalignments occurs over the operating temperature range. In accordance with another aspect of the present disclosure, optical assembly 10 or 210 may be used in conjunction with other cooling devices, such as liquid coolers or fans, that are able to maintain the internal components of the optical assembly 10 or 210 within an operating temperature range that is less than the overall temperature operating range from about −54° C. to about 71° C.

In accordance with another aspect of the present disclosure, optical assembly 10 or 210 enables the mirror 14 to be used in conjunction with devices that move the mirror 14 that do not necessarily rely on mechanical movement such as MEMS. Optical assembly 10 or 210 improves overall performance of the total optical system by having control or compensation over the angular drift. Otherwise, a system would need to have a high optical laser power. For example, when the optical laser power is high, the margin for error increases, but when the temperature goes above the normal operating range, the system must account for an amount of decrease in performance because mirrors or mounts have a tendency to shift or drift and the overall efficiency of the laser system decreases. Thus, optical assembly 10 or 210 enables to compensate for a laser system that has a lower power and energy from an electromechanical standpoint under perfect conditions.

In operation, computer 74 may operate in conjunction with a feedback loop that operates with the temperature sensors 70, 72 of the supports 16, 18 that is able to read a calibration file stored in the memory 78 and is executed by the processor 76 which determines, based on the temperatures observed by the sensors 70, 72 and the first and second CTEs stored in the memory 78, the angle 54 that is to be achieved and the resultant heat transfer that needs to occur across arrows 88 or 86 to effectuate the accomplishment of tilting the mirror 14 to compensate for the alignment drift. The feedback loop may operate continuously by sensing the temperatures observed by the sensor 70, 72 over connections 82 and 84 so that the thermoelectric module 60 may receive signals via connection 80 continuously to vary the tilt angle of change about axis 54. In one particular example, the feedback utilizes a calibration and lookup approach for the table stored in the memory 78.

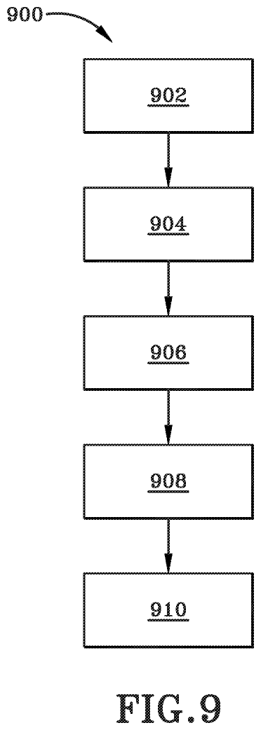

FIG. 9 depicts, via a flow chart, an exemplary method of the optical assembly 10 or 210 generally at 900. Method 900 may include sensing a first temperature of a first support having a first coefficient of thermal expansion (CTE) coupled to an optical mirror tiltable about a first tilt axis, which is shown generally at 902. Method 900 may include sensing a second temperature of a second support having a second CTE coupled to the optical mirror, which is shown generally at 904. Method 900 may include determining whether the optical mirror needs to be tilted about the first tilt axis based, at least in part, on the first temperature, the first CTE, the second temperature, and the second CTE, which is shown generally at 906. Method 900 may include tilting the optical mirror, which is shown generally at 908. Method 900 may include minimizing angular drift of the optical mirror by reducing an alignment mismatch between the optical mirror and a frame of the optical assembly, which is shown generally at 910. The method 900 may further provide transferring heat to (i.e., in the direction of arrow 88) or from (i.e., the direction of arrow 86) the first support in response to sensing the first temperature. Method 900 may include transferring heat to or from the second support in response to sensing the second temperature. Method 900 may include correcting a beam reflection angle from the optical mirror in response to the transferring heat to or from the first support. Method 900 may include correcting the beam reflection angle within an angular range from about 1 urad to about 1 mrad, wherein the angular range is less than correction capabilities effectuated by mechanical devices, such as a MEMS device or a gimbal; thus, optical assembly 10 or 210 may, in one particular embodiment, be free of any mechanical device that corrects alignment drift. Method 900 may include expanding the first support linearly along a support axis that is orthogonal to the first tilt axis; and contracting the first support linearly along the support axis.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The indefinite articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. An optical assembly comprising:
an optical mirror adapted to receive and reflect a beam of electromagnetic radiation;
a first support coupled to the optical mirror having a first coefficient of thermal expansion (CTE);
a second support coupled to the optical mirror having a second CTE;
a first tilt axis of the optical mirror;
a temperature operating range, wherein the optical mirror tilts about the first tilt axis as the first support and the second support expand or contract in response to the first CTE and the second CTE, respectively, as temperatures of the first support and the second support vary within the temperature operating range.

2. The optical assembly of claim 1, further comprising:
a variable optical beam deflection angle;
a first temperature within the temperature operating range;
a different second temperature within the temperature operating range;
wherein the mirror tilts about the first tilts axis to vary the variable optical beam deflection angle as the temperature changes from the first temperature to the second temperature.

3. The optical assembly of claim 2, further comprising:
wherein a greater temperature difference between the first temperature and the second temperature results in a greater optical beam deflection angle than a lesser temperature difference between the first temperature and the second temperature.

4. The optical assembly of claim 3, further comprising:
a range of the variable optical beam deflection angle from about 1 urad to about 1 mrad; and
a range of the temperature difference between the first temperature and the second temperature in a range from about 1° C. to about 125° C.

5. The optical assembly of claim 3, wherein the first CTE is different than the second CTE.

6. The optical assembly of claim 1, further comprising:
a first surface and an opposing second surface of the optical mirror;
an insulator coupled to the second surface of the optical mirror;
a portion of the first support connected to the insulator;
a portion of the second support connected to the insulator; and
wherein the insulator is positioned between the optical mirror and the first and second supports.

7. The optical assembly of claim 1, further comprising:
a first surface and an opposing second surface of the optical mirror;
wherein the first support and second support are offset from the second surface of the optical mirror;
a thermoelectric module coupled to the first support and the second support to exchange heat between the first support and the second support; and
wherein the first and second supports expand or contract in response to the heat exchanged between the first support and the second support.

8. The optical assembly of claim 7, further comprising:
a spacing distance defined between the first support and the second support;
a first end of the thermoelectric module coupled to the first support;
a second end of the thermoelectric module coupled to the second support; and
wherein the thermoelectric module occupies the spacing distance between the first and second supports offset from the second surface of the optical mirror.

9. The optical assembly of claim 8, further comprising:
a first temperature sensor associated with the first support;
a second temperature sensor associated with the second support;
a computer having a processor and a non-transitory computer readable storage medium;
a first electrical connection between the thermoelectric module and the computer, wherein the storage medium has instructions encoded thereon that, when executed by the processor, implement operations to exchange heat between the first support and the second support;
a second electrical connection between the first temperature sensor and the computer; and
a third electrical connection between the second temperature sensor and the computer.

10. The optical assembly of claim 9, further comprising:
a simultaneously execution of signals transmitted along the second and third electrical connections by the processor; and
a command transmitted along the first electrical connection to the thermoelectric modules to selectively change the temperature of the first support relative to the second support to tilt the mirror about the first tilt axis as the first support expands or contracts relative to the second support.

11. The optical assembly of claim 9, further comprising:
a direct conduction of heat between the thermoelectric couple and the first support; and
a direction conduction of heat between the thermoelectric couple and the second support.

12. The optical assembly of claim 1, further comprising:
a thermoelectric module coupled to the first support configured to selectively (i) heat the first support to expand the first support, and (ii) cool the first support to contract the first support;
wherein the second CTE approximates zero such that the second support is substantially invariable over the temperature operating range;
a variable optical beam deflection angle; and
wherein the mirror tilts about the first tilts axis to vary the variable optical beam deflection angle as the thermoelectric module changes the temperature of the first support to expand or contract.

13. The optical assembly of claim 1, further comprising:
a relationship of the variable optical beam deflection angle versus the temperature difference between the first temperature and the second temperature that is linear or non-linear.

14. A method for an optical assembly comprising:
sensing a first temperature of a first support having a first coefficient of thermal expansion (CTE) coupled to an optical mirror tiltable about a first tilt axis;
sensing a second temperature of a second support having a second CTE coupled to the optical mirror;
determining whether the optical mirror needs to be tilted about the first tilt axis based, at least in part, on the first temperature, the first CTE, the second temperature, and the second CTE;
tilting the optical mirror; and
minimizing angular drift of the optical mirror by reducing an alignment mismatch between the optical mirror and a frame of the optical assembly.

15. The method of claim 14, further comprising:
transferring heat to or from the first support in response to sensing the first temperature.

16. The method of claim 15, further comprising:
transferring heat to or from the second support in response to sensing the second temperature.

17. The method of claim 15, further comprising:
correcting a beam reflection angle from the optical mirror in response to the transferring heat to or from the first support.

18. The method of claim 17, further comprising:
correcting the beam reflection angle within an angular range from about 1 urad to about 1 mrad, wherein the angular range is less than correction capabilities effectuated by mechanical devices.

19. The method of claim 18, further comprising:
expanding the first support linearly along a support axis that is orthogonal to the first tilt axis; and
contracting the first support linearly along the support axis.

20. The method of claim 19, further comprising:
moving the optical assembly through an environment that varies in temperature ranging from about −54° C. to about 71° C., wherein temperature variations cause angular drift of the mirror thereby reducing efficiency of the optical assembly; and
eliminating angular drift by removing the alignment mismatch between the optical mirror and the frame of the optical assembly.
